(19) United States
(12) Patent Application Publication
(10) Pub. No.: US 2026/0088761 A1
(43) Pub. Date: Mar. 26, 2026

(54) MODULATOR, MANUFACTURING METHOD, AND TRANSMITTING APPARATUS

(71) Applicant: HUAWEI TECHNOLOGIES CO., LTD., Shenzhen (CN)

(72) Inventor: Oupeng Li, Chengdu (CN)

(73) Assignee: HUAWEI TECHNOLOGIES CO., LTD., Shenzhen (CN)

(21) Appl. No.: 19/398,222

(22) Filed: Nov. 24, 2025

Related U.S. Application Data
(63) Continuation of application No. PCT/CN2023/096126, filed on May 24, 2023.

(51) Int. Cl. H03C 7/02

(52) U.S. Cl. CPC H03C 7/027; H03C 2200/0033

(57) ABSTRACT

A modulator, a manufacturing method, and a transmitting apparatus are provided, applied to the field of wireless communication technologies. The modulator includes a first modulation circuit. The first modulation circuit includes a diode and a first microstrip. The first microstrip includes a first metal wire, a second metal wire, and an intermediate medium. The first metal wire and the second metal wire are disposed in parallel on a first surface of the intermediate medium along a first straight line. A first end of the first metal wire is opposite to a second end of the second metal wire, and a first spacing area with a spacing distance equal to a first value exists between the first end of the first metal wire and the second end of the second metal wire. A second end of the first metal wire is coupled to an anode of the diode.

### CROSS-REFERENCE TO RELATED APPLICATIONS

This application is a continuation of International Application No. PCT/CN2023/096126, filed on May 24, 2023, the disclosure of which is hereby incorporated by reference in its entirety.

### TECHNICAL FIELD

This application relates to the field of wireless communication technologies, and in particular, to a modulator, a manufacturing method, and a transmitting apparatus.

### BACKGROUND

Wireless communication is based on a transmitting apparatus and a receiving apparatus. An existing transmitting apparatus includes a digital-to-analog converter, a frequency generator, a modulator, and a power amplifier. The digital-to-analog converter converts a data signal in a digital signal form into a data signal in an analog signal form. The frequency generator outputs a radio electromagnetic wave signal to the modulator. The modulator modulates the data signal in the analog signal form to the radio electromagnetic wave signal, to obtain a wireless communication signal. After the power amplifier performs power amplification on the wireless communication signal, the transmitting apparatus sends an amplified wireless communication signal to the receiving apparatus. The receiving apparatus obtains, by demodulating the wireless communication signal, a data signal modulated on the transmitting apparatus side, to complete wireless communication of the data signal. However, with development of wireless communication, when bands of the wireless communication signal and the radio electromagnetic wave signal reach terahertz bands or above, power consumption and costs of using digital-to-analog converters for digital-to-analog conversion increase sharply.

Based on this, an implementation of wireless communication is as follows: A baseband processing circuit, a frequency generator, and a direct modulator are disposed in the transmitting apparatus. The baseband processing circuit outputs data signals in a digital signal form. The frequency generator generates radio electromagnetic wave signals in the terahertz band or above. The direct modulator directly modulates, based on the data signals in the digital signal form, the radio electromagnetic wave signals in the terahertz band or above, to obtain wireless communication signals in the terahertz band. The process of performing direct modulation on radio electromagnetic wave signals in the terahertz band based on the data signals in the digital signal form can avoid excessively high power consumption and costs that are originally required for using the digital-to-analog converter. However, such a solution is limited by device parameters of the direct modulator, restricting the precision and other aspects of direct modulation on radio electromagnetic wave signals in the terahertz band or above.

### SUMMARY

Embodiments of this application provide a modulator, a manufacturing method, and a transmitting apparatus, to improve precision of direct modulation performed, by a direct modulator based on a digital signal, on a radio electromagnetic wave signal in a terahertz band and above, and the like.

To achieve the foregoing objectives, the following technical solutions are used in embodiments of this application.

According to a first aspect, a modulator is provided. The modulator includes a first modulation circuit. The first modulation circuit includes a diode and a first microstrip. The first microstrip includes a first metal wire, a second metal wire, and an intermediate medium. The first metal wire and the second metal wire are disposed in parallel on a first surface of the intermediate medium along a first straight line. A first end of the first metal wire is opposite to a second end of the second metal wire, and a first spacing area with a spacing distance equal to a first value exists between the first end of the first metal wire and the second end of the second metal wire. A second end of the first metal wire is coupled to an anode of the diode.

In this embodiment of this application, the first metal wire and the second metal wire form the first spacing area. During actual application, a radio electromagnetic wave signal may be input into a first end of the second metal wire in the first microstrip. A data signal in a digital signal form is input into the anode of the diode. Then, the radio electromagnetic wave signal that is output after being transmitted and reflected by the first microstrip and the diode is received from the first end of the second metal wire. The radio electromagnetic wave signal that is output after being transmitted and reflected is a wireless communication signal obtained through direct phase modulation. A specific process of the direct phase modulation is as follows: The radio electromagnetic wave signal is sequentially transmitted from the second metal wire to the first metal wire and the diode, and the diode is controlled to be turned on or turned off by using the data signal in the digital signal form. In two different cases in which the diode is turned on and the diode is turned off, the radio electromagnetic wave signal may be reflected from the first metal wire to the second metal wire based on two different reflection coefficients. In the case of the two different reflection coefficients, radio electromagnetic wave signals obtained through reflection have different phases. The radio electromagnetic wave signals obtained through reflection are used as wireless communication signals obtained through the direct phase modulation. However, during the direct phase modulation, it is difficult for the diode to directly implement transmission matching with the first microstrip. To implement transmission matching, the first spacing area formed between the first metal wire and the second metal wire may cause an equivalent capacitance created between the first metal wire and the second metal wire, and the formed equivalent capacitance is used to adjust transmission impedance between the diode and the first microstrip, to implement transmission matching. Alternatively, the first spacing area may be considered as an admittance structure, and transmission matching between the diode and the first microstrip is implemented through the admittance structure.

In a possible implementation, the first microstrip further includes a metal resonant ring. The metal resonant ring is disposed on the first surface, and is located on a side of the first spacing area opposite the first metal wire and the second metal wire. In this embodiment of this application, the first spacing area has a specific frequency response, and a frequency and the like of the frequency response may be adjusted based on the metal resonant ring, to increase an application bandwidth of the direct phase modulation.

In a possible implementation, the metal resonant ring includes a first ring segment with a length of a third value. The first ring segment and the first straight line maintain a vertical shortest distance of a second value. In this embodiment of this application, the length (that is, the third value) of the first ring segment may be adaptively adjusted and set based on a frequency of an actually modulated radio electromagnetic wave signal, a bandwidth needed for application, and the like, so that coupling strength between the metal resonant ring and the first spacing area may be adjusted, to implement application of a corresponding frequency and bandwidth.

In a possible implementation, a connection line between a midpoint of the metal resonant ring and a midpoint of the first spacing area is perpendicular to the first straight line. In this embodiment of this application, when the connection line between the midpoint of the metal resonant ring and the midpoint of the first spacing area is perpendicular to an extension line (that is, the first straight line) of the first metal wire and the second metal wire, the metal resonant ring achieves a better adjustment effect on the first spacing area. In addition, in the implementation, it is more convenient to adjust parameters such as the length of the first ring segment of the metal resonant ring to correspond to a needed frequency and bandwidth, and the like.

In a possible implementation, an open slot is provided on a side of the metal resonant ring that is away from the first metal wire and the second metal wire. A slot spacing of the open slot is a fourth value. In this embodiment of this application, the slot spacing (that is, the fourth value) of the open slot is adjusted, so that a response frequency of the metal resonant ring, the first spacing area, or the like may be adjusted, to adjust an impedance capacitance value of the metal resonant ring, to adjust a bandwidth needed for actual application.

In a possible implementation, a second end of a first coupler is a through end relative to a first end of the first coupler. A third end of the first coupler is a coupling end relative to the first end of the first coupler. The second end and the third end of the first coupler are respectively coupled, via first coupling, a corresponding first modulation circuit, where first coupling refers to coupling the corresponding first coupler via a first end of the second metal wire of the first modulation circuit. In this embodiment of this application, one first coupler may be coupled to two first modulation circuits, allowing the two first modulation circuits to simultaneously modulate the radio electromagnetic wave signal. In this case, reflection coefficients of the two first modulation circuits may be respectively controlled by using a data signal of 1 bit. Alternatively, a reflection coefficient of one first modulation circuit may be correspondingly controlled by using a data signal of 2 bits.

For example, the modulator may include a second modulation circuit. One second modulation circuit includes a first coupler and two first modulation circuits. Direct phase modulation on the radio electromagnetic wave signal is implemented by using the second modulation circuit.

In a possible implementation, a second end of a second coupler is a through end relative to a first end of the second coupler. A third end of the second coupler is a coupling end relative to the first end of the second coupler. A fourth end of the first coupler is an isolation end relative to the first end of the first coupler. The second end and the third end of the second coupler are separately coupled, via second coupling, to a corresponding first coupler in the second modulation circuit, where the second coupling refers to coupling the corresponding second coupler via the first end of the first coupler. A first input end and a second input end of a power combiner are respectively coupled, via third coupling, to a corresponding first coupler, where the third coupling refers to coupling the corresponding power combiner via the fourth end of the first coupler. In this embodiment of this application, the radio electromagnetic wave signal may be divided into I radio electromagnetic wave signals and Q radio electromagnetic wave signals through a second coupler in a third modulation circuit. In addition, based on the two second modulation circuits, I-phase modulation of the I radio electromagnetic wave signal and Q-phase modulation of the Q radio electromagnetic wave signals may be respectively implemented, to obtain I wireless communication signals and Q wireless communication signals. The power combiner performs vector synthesis on the I wireless communication signals and the Q wireless communication signals to obtain a radio electromagnetic wave signal that is subject to quadrature phase shift keying modulation. Similarly, quadrature amplitude modulation may be further performed on the radio electromagnetic wave signal. Specifically, on the basis of performing phase modulation on the radio electromagnetic wave signal by the third modulation circuit, amplitude modulation is performed on the radio electromagnetic wave signal, to obtain a wireless communication signal having phase information and amplitude information.

For example, the modulator may include a third modulation circuit. One third modulation circuit includes a second coupler, a power combiner, and two second modulation circuits. In this embodiment of this application, a quadrature phase shift keying modulator may be formed by using the third modulation circuit.

In a possible implementation, the diode may be invertedly coupled to the first microstrip. In this case, the first microstrip further includes a ground metal plate and a third metal wire. The ground metal plate is coupled to a second surface of the intermediate medium. The first surface and the second surface are two opposite surfaces of the intermediate medium. A through hole running through the first surface and the second surface is provided on the intermediate medium. A second end of the third metal wire penetrates into the through hole from the first surface and is coupled to the ground metal plate. A cathode of the diode is coupled to a first end of the third metal wire. In this embodiment of this application, the diode may be invertedly coupled to the first microstrip. In this case, the through hole and the third metal wire are provided on the intermediate medium of the first microstrip, and the diode is grounded after being coupled to the first microstrip through the through hole and the third metal wire. For example, the anode of the diode may be sintered (sintered) and coupled to the second end of the first metal wire by using an epoxy conductive material. The cathode of the diode is sintered and coupled to the first end of the third metal wire by using the epoxy conductive material.

In a possible implementation, the diode is coupled in a non-flipped orientation to the first microstrip. In this case, the first microstrip further includes a ground metal plate, a third metal wire, a first air bridge, and a second air bridge. The ground metal plate is coupled to the second surface of the intermediate medium. The first surface and the second surface are two opposite surfaces of the intermediate medium. A through hole running through the first surface and the second surface is provided on the intermediate medium. A second end of the third metal wire is coupled to the ground metal plate after extending from the first surface into the through hole. A body of the diode is grown on the first surface, a cathode of the diode is coupled to a first end of the third metal wire through the first air bridge, and the anode of the diode is coupled to the second end of the first metal wire through the second air bridge. In this embodiment of this application, the diode is coupled in a non-flipped orientation to the first microstrip. In this case, the cathode of the diode may be electrically connected to the first end of the third metal wire through the first air bridge. The anode of the diode is electrically connected to the first end of the first metal wire through the second air bridge.

In a possible implementation, the intermediate medium and the diode may be based on a same material. For example, the intermediate medium is gallium arsenide. The diode is based on gallium arsenide. In this embodiment of this application, the diode made of a gallium arsenide material is applicable to phase modulation in a terahertz band. The intermediate medium may also be a gallium arsenide material, or may be a quartz material, or the like. During actual application, the intermediate medium and the diode may be obtained based on the gallium arsenide material. When the diode is based on the gallium arsenide material, a substrate of the diode is gallium arsenide, and the intermediate medium may be reused as the substrate of the diode.

In a possible implementation, the body of the diode includes a buffer layer, an epitaxial layer, and a passivation layer that are sequentially stacked on the first surface from bottom to top. The cathode of the diode and the anode of the diode are respectively grown on two sides of an upper end surface of the buffer layer. In this embodiment of this application, when the intermediate medium is reused as the substrate of the diode, only a body structure of the diode that does not include the substrate needs to be grown on the intermediate medium. The body structure includes the buffer layer, the epitaxial layer, and the passivation layer that are sequentially stacked. The buffer layer may be heavily doped gallium arsenide, the epitaxial layer may be lightly doped gallium arsenide, and the passivation layer may be silicon dioxide.

In a possible implementation, the diode further includes a third air bridge, a vacant slot exists on the body of the diode, the vacant slot is located in a middle section of the buffer layer, the epitaxial layer, and the passivation layer, a first end of the third air bridge is coupled to the anode of the diode, and a second end of the third air bridge is coupled to the passivation layer on a side of the cathode of the diode across the vacant slot. In this embodiment of this application, when the diode is a Schottky diode, the third air bridge may be further disposed on the diode, to form a Schottky diode structure.

According to a second aspect, an embodiment of this application further provides a manufacturing method, for manufacturing the modulator recorded in the first aspect. The modulator includes a first modulation circuit, and the first modulation circuit includes a diode and a first microstrip. The first microstrip includes a first metal wire, a second metal wire, and an intermediate medium. The method includes: forming a first bright area on the intermediate medium; and obtaining the first metal wire and the second metal wire through etching (etching) based on the first bright area. The first metal wire and the second metal wire are disposed in parallel on a first surface of the intermediate medium along a first straight line. A first end of the first metal wire is opposite to a second end of the second metal wire, and a first spacing area with a spacing distance equal to a first value exists between the first end of the first metal wire and the second end of the second metal wire. A second end of the first metal wire is coupled to an anode of the diode.

In a possible implementation, the first microstrip further includes a metal resonant ring. The method further includes: obtaining the metal resonant ring through etching based on the first bright area. The metal resonant ring is disposed on a second surface, and is located on a side of the first spacing area opposite the first metal wire and the second metal wire.

In a possible implementation, the metal resonant ring includes a first ring segment with a length of a third value. The first ring segment and the first straight line maintain a vertical shortest distance of a second value.

In a possible implementation, a connection line between a midpoint of the metal resonant ring and a midpoint of the first spacing area is perpendicular to the first straight line.

In a possible implementation, an open slot is provided on a side of the metal resonant ring that is away from the first metal wire and the second metal wire. A slot spacing of the open slot is a fourth value.

In a possible implementation, the first microstrip further includes a ground metal plate and a third metal wire. The method further includes: before the first bright area is formed on the intermediate medium by using photoresist, processing a through hole on the intermediate medium, where the through hole runs through the first surface and the second surface of the intermediate medium, and the first surface and the second surface are two opposite surfaces of the intermediate medium, depositing (depositing) the ground metal plate on the second surface, and obtaining the third metal wire through etching based on the first bright area, where a second end of the third metal wire penetrates into the through hole from the first surface and is coupled to the ground metal plate; and invertedly sintering the diode on the first surface of the intermediate medium, where a cathode of the diode is coupled to a first end of the third metal wire. In this embodiment of this application, the diode and the first microstrip may be processed separately and independently, and then sintered and coupled together. In the processing process, costs of the modulator are low, and the modulator is easy to maintain.

In a possible implementation, the first microstrip further includes a ground metal plate, a third metal wire, a first air bridge, and a second air bridge. The method further includes: growing a body of the diode on the first surface of the intermediate medium; obtaining a first part of the third metal wire, the first air bridge, and the second air bridge through etching based on the first bright area, where the first part of the third metal wire includes a first end of the third metal wire, a cathode of the diode is coupled to the first end of the third metal wire through the first air bridge, and the anode of the diode is coupled to the second end of the first metal wire through the second air bridge; processing a through hole on the intermediate medium, where the through hole runs through the first surface and the second surface of the intermediate medium, and the first surface and the second surface are two opposite surfaces of the intermediate medium; and depositing a second part of the third metal wire in the through hole, and depositing the ground metal plate on the second surface, where the second part of the third metal wire includes a second end of the third metal wire, and the second end of the third metal wire is coupled to the ground metal plate. In this embodiment of this application, the first microstrip and the diode are processed and manufactured together. In comparison with the foregoing embodiment in which the first microstrip and the diode are independently processed, modulation performance and the like of the modulator that are obtained in this embodiment are better.

In a possible implementation, the intermediate medium is gallium arsenide. The diode is based on gallium arsenide.

In a possible implementation, the body of the diode includes a buffer layer, an epitaxial layer, and a passivation layer. The growing the body of the diode on the first surface of the intermediate medium includes: sequentially growing the buffer layer, the epitaxial layer, and the passivation layer from bottom to top on the first surface of the intermediate medium; and respectively depositing the anode of the diode and the cathode of the diode on two sides of an upper end surface of the buffer layer.

In a possible implementation, the diode further includes a third air bridge. The method further includes: before the first bright area is formed on the intermediate medium by using photoresist, obtaining a vacant slot through etching on a middle section of the buffer layer, the epitaxial layer, and the passivation layer; and obtaining the third air bridge through etching in the first bright area, where a first end of the third air bridge is coupled to the anode of the diode, and a second end of the third air bridge is coupled to the passivation layer on a side of the cathode of the diode across the vacant slot.

According to a third aspect, an embodiment of this application further provides a transmitting apparatus. The transmitting apparatus includes a circuit board and the modulator recorded in the first aspect, and the modulator is disposed on the circuit board.

In a possible implementation, the transmitting apparatus further includes a frequency generator and a circuit board of a processing circuit. An output end of the processing circuit is coupled to a first input end of the modulator, and an output end of the frequency generator is coupled to a second input end of the modulator. The frequency generator is configured to output a radio electromagnetic wave signal to the modulator. The processing circuit is configured to output a data signal including at least one bit to the modulator. The modulator is configured to perform phase modulation on the radio electromagnetic wave signal based on the data signal, to obtain a phase-modulated wireless communication signal. A phase of the wireless communication signal indicates a value of the at least one bit of the data signal.

In a possible implementation, the transmitting apparatus further includes a frequency multiplier. The output end of the frequency generator is coupled to the second input end of the modulator through the frequency multiplier.

According to a fourth aspect, an embodiment of this application further provides a chip system. The chip system includes at least one controller and at least one interface circuit. The at least one controller and the at least one interface circuit may be interconnected through a line. The controller is configured to support the chip system in implementing functions or steps in the foregoing embodiments. The at least one interface circuit may be configured to receive a signal from another apparatus (for example, a communication interface, a baseband processing circuit, a direct modulator, or a frequency generator), or send a signal to another apparatus (for example, a communication interface, a baseband processing circuit, a direct modulator, or a frequency generator). The chip system may include a chip, and may further include another discrete component.

For descriptions of technical principles and beneficial effects of the second aspect, the third aspect, and the fourth aspect, refer to related descriptions of the first aspect. Details are not described herein again.

### BRIEF DESCRIPTION OF DRAWINGS

FIG. 1 is a diagram of a structure of a first transmitting apparatus according to an embodiment of this application;

FIG. 2 is a diagram of a structure of a second transmitting apparatus according to an embodiment of this application;

FIG. 3 is a diagram of a structure of a first modulator according to an embodiment of this application;

FIG. 4 is a diagram 1 of a structure of a first modulation circuit according to an embodiment of this application;

FIG. 5 is a schematic side sectional view of a structure of a first microstrip according to an embodiment of this application;

FIG. 6 is a diagram 2 of a structure of another first modulation circuit according to an embodiment of this application;

FIG. 7 is a diagram of a structure of a diode according to an embodiment of this application;

FIG. 8 is a diagram 3 of a structure of another first modulation circuit according to an embodiment of this application;

FIG. 9 is a diagram 4 of a structure of another first modulation circuit according to an embodiment of this application;

FIG. 10 is a diagram of a structure of a second modulation circuit according to an embodiment of this application;

FIG. 11 is a diagram of a structure of a coupler according to an embodiment of this application;

FIG. 12 is a diagram of a structure of a third modulation circuit according to an embodiment of this application;

FIG. 13 is a diagram of a structure of a power combiner according to an embodiment of this application;

FIG. 14 is a diagram of a QPSK phase modulation vector constellation diagram based on the third modulation circuit shown in FIG. 12 according to an embodiment of this application;

FIG. 15 is a diagram of a structure of another second transmitting apparatus according to an embodiment of this application;

FIG. 16 is a schematic flowchart of a manufacturing method according to an embodiment of this application;

FIG. 17 is a diagram of processing based on the manufacturing method shown in FIG. 16 according to an embodiment of this application;

FIG. 18 is another diagram of processing based on the manufacturing method shown in FIG. 16 according to an embodiment of this application;

FIG. 19 is a schematic flowchart of another manufacturing method according to an embodiment of this application;

FIG. 20 is a diagram 1 of processing based on the manufacturing method shown in FIG. 19 according to an embodiment of this application;

FIG. 21 is another diagram 2 of processing based on the manufacturing method shown in FIG. 19 according to an embodiment of this application;

FIG. 22 is still another diagram 3 of processing based on the manufacturing method shown in FIG. 19 according to an embodiment of this application;

FIG. 23 is still another diagram 4 of processing based on the manufacturing method shown in FIG. 19 according to an embodiment of this application;

FIG. 24 is still another diagram 5 of processing based on the manufacturing method shown in FIG. 19 according to an embodiment of this application; and

FIG. 25 is still another diagram 6 of processing based on the manufacturing method shown in FIG. 19 according to an embodiment of this application.

### DESCRIPTION OF EMBODIMENTS

It should be noted that the terms such as “first” and “second” in embodiments of this application are merely used to distinguish between features of a same type, and cannot be understood as an indication of relative importance, a quantity, a sequence, or the like.

The terms such as “example” or “for example” in embodiments of this application are used to represent giving an example, an illustration, or a description. Any embodiment or design solution described as “example” or “for example” in this application should not be construed as being preferred or advantageous over other embodiments or design solutions. To be precise, use of the terms such as “example” or “for example” is intended to present a relative concept in a specific manner.

The terms “coupling” and “connection” in embodiments of this application should be understood in a broad sense. For example, the terms may be a physical direct connection, or may be an indirect connection implemented through an electronic component, for example, a connection implemented through a resistor, an inductor, a capacitor, or another electronic component.

First, some basic concepts in embodiments of this application are explained and described.

Wireless communication: Wireless communication is based on a transmitting apparatus and a receiving apparatus. The transmitting apparatus modulates a data signal to a radio electromagnetic wave signal to obtain a wireless communication signal, and transmits the wireless communication signal. The receiving apparatus receives the wireless communication signal, and obtains, through demodulation, the data signal carried in the wireless communication signal, to complete the wireless communication.

Terahertz band (THz): Signals in terahertz band are radio electromagnetic wave signals with frequencies ranging from 0.1 THz to 10 THz. The frequency of the radio electromagnetic wave signal in the terahertz band is between a microwave band and an infrared band, possessing the characteristics of low quantum energy, large bandwidth, and good penetrability. Wireless transmission performed on the radio electromagnetic wave signal in the terahertz band is currently a most effective technical means for real-time wireless transmission of massive data. In comparison with wireless communication based on a millimeter band and below, wireless communication in the terahertz band has advantages of larger bandwidth and higher information transmission capacities. The radio electromagnetic wave signal in the terahertz band has attracted much attention in communication applications. Currently, there is a related standard (IEEE 802.15.3d) for a terahertz band of 300 GHz, and it is expected in the industry that an electromagnetic wave signal in the terahertz band is to be used in a 6th generation mobile communication technology (6th generation mobile communication technology, 6G).

Modulation: It is a process of transferring information based on changes of a related parameter (for example, an amplitude, a frequency, or a phase) of a radio electromagnetic wave signal, and map to-be-sent data (for example, a bit sequence) to a modulation symbol.

For example, quadrature modulation may be used in a communication system (for example, a new radio (new radio, NR) system or a long term evolution (long term evolution, LTE) system). The quadrature modulation may mean that a transmit end (for example, a network device, a terminal device, or a transmitting apparatus) uses two radio electromagnetic wave signals that have a same frequency and that are orthogonal to each other (where for example, a phase difference is 90°) as a carrier and a data signal for modulation, to obtain a wireless communication signal that is subject to the quadrature modulation. The quadrature modulation may also be referred to as IQ modulation. I may represent an in-phase (in-phase) component (that is, radio electromagnetic wave signals with a same phase), and Q may represent a quadrature (quadrature) component (that is, radio electromagnetic wave signals with a phase difference of 90°). In other words, data that is subject to quadrature modulation may include I components and Q components that are orthogonal to each other, so that the I components and the Q components may be considered as two dimensions that may be independently detected at a receive end.

For example, the modulation symbol may be represented by using a complex value, for example, may be determined by using Formula (1).

$$x = a + i \cdot b = a \cdot cos ω t + b \cdot sin ω t \qquad Formula ( 1 )$$

In Formula (1), x may represent a wireless communication signal obtained through quadrature modulation. a may represent an amplitude of the I components. b may represent an amplitude of the Q components. cos ωt may represent I radio electromagnetic wave signals used during modulation of the I components. sin ωt may represent Q radio electromagnetic wave signals used during modulation of the Q components. ω represents a frequency of the radio electromagnetic wave signal.

The quadrature modulation may include: binary phase shift keying (binary phase shift keying, BPSK), π/2-BPSK, quadrature phase shift keying (quadrature phase shift keying, QPSK), quadrature amplitude modulation (quadrature amplitude modulation, QAM), or the like. For example, the BPSK and the QPSK may mean to transfer information based on a phase change of the radio electromagnetic wave signal, and maintain an amplitude and the frequency of the radio electromagnetic wave signal unchanged. The QAM may mean to transfer information based on an amplitude change and the phase change of the radio electromagnetic wave signal, and maintain the frequency of the radio electromagnetic wave signal unchanged. It may be understood that, in the BPSK, one modulation symbol may carry 1 bit (where there are a total of two types: “0” and “1”), and there are a total of two different modulation symbols. In the QPSK, 2 bits may form a group (where there are a total of four composition manners: “00”, “01” “11”, and “10”), so that one wireless communication signal may carry 2 bits, and there are a total of four different modulation symbols. In 2^{m}-QAM, a modulation order is m, and one modulation symbol may carry m bits, in other words, there are a total of 2^{m} different modulation symbols.

A constellation diagram (constellation diagram) may be used to define amplitude information and phase information of a wireless communication signal obtained through modulation, in other words, the wireless communication signal may be represented by a constellation point in the constellation diagram. The constellation diagram includes an I axis (which, for example, may be a horizontal coordinate axis in the constellation diagram) and a Q axis (which, for example, may be a vertical coordinate axis in the constellation diagram), and the constellation point may be represented in a vector form (for example, (I, Q)).

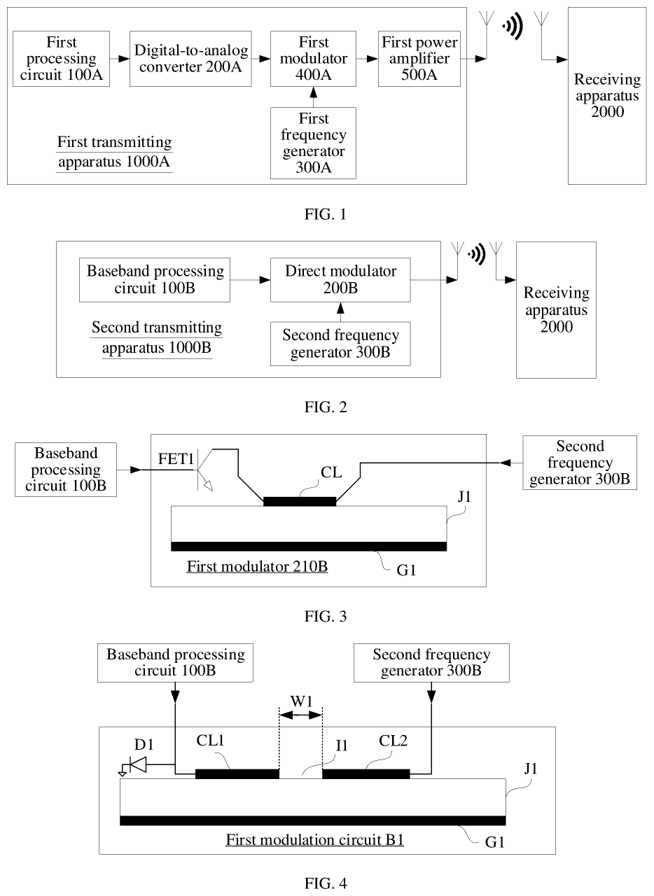

FIG. 1 is a diagram of a structure of a first transmitting apparatus 1000A according to an embodiment of this application. The first transmitting apparatus 1000A includes a first processing circuit 100A, a digital-to-analog converter 200A, a first frequency generator 300A, a first modulator 400A, and a first power amplifier 500A. An output end of the first processing circuit 100A is coupled to an input end of the digital-to-analog converter 200A. An output end of the digital-to-analog converter 200A is coupled to a first input end of the first modulator 400A. An output end of the first frequency generator 300A is coupled to a second input end of the first modulator 400A. An output end of the first modulator 400A is coupled to an input end of the first power amplifier 500A. The first processing circuit 100A is configured to output a first data signal in a digital signal form to the digital-to-analog converter 200A. The digital-to-analog converter 200A is configured to convert the first data signal in the digital signal form into a first data signal in an analog signal form, and output the first data signal in the analog signal form to the first modulator 400A. The first frequency generator 300A is configured to output a radio electromagnetic wave signal to the first modulator 400A. The first modulator 400A is configured to modulate the radio electromagnetic wave signal based on the first data signal in the analog signal form, to obtain a wireless communication signal. The first power amplifier 500A is configured to amplify the wireless communication signal. The first transmitting apparatus 1000A transmits an amplified wireless communication signal. A receiving apparatus 2000 receives the amplified wireless communication signal, and obtains, through demodulation, the first data signal, to complete wireless communication.

In this embodiment of this application, the first processing circuit 100A performs, in a digital domain, an operation such as operation processing on the first data signal in the digital signal form. When the first data signal needs to be sent, the first data signal in the digital signal form needs to be converted into the first data signal in the analog signal form by the digital-to-analog converter 200A, and then the first data signal in the analog signal form is modulated to the radio electromagnetic wave signal for transmission. With development of wireless communication technologies, during communication, a band of a radio electromagnetic wave signal used as a carrier signal is also continuously increasing. In a 5th generation mobile communication technology (5th generation mobile communication technology, 5G), a band of a radio electromagnetic wave signal has reached a millimeter band, and a large amount of data can be transmitted in real time. This has a very high requirement on a bandwidth and processing precision of the digital-to-analog converter 200A. However, an amount of data that can be transmitted in real time when the band of the radio electromagnetic wave signal reaches a terahertz band is far greater than an amount of data that can be transmitted in real time in the millimeter band. In this case, if the first transmitting apparatus 1000A is still used to implement wireless communication, a higher requirement is imposed on the bandwidth and the processing precision of the digital-to-analog converter 200A. This also means that more costs are required for manufacturing the digital-to-analog converter 200A, and the digital-to-analog converter 200A also generates more power consumption. In addition, a frequency of a wireless communication signal in the terahertz band is very high, and it is difficult to adapt to an appropriate first power amplifier 500A.

To reduce power consumption and costs caused by the digital-to-analog converter 200A during wireless communication of a high-band radio electromagnetic wave signal, an embodiment of this application provides a second transmitting apparatus. As shown in FIG. 2, the second transmitting apparatus 1000B includes a circuit board, a baseband processing circuit 100B, a direct modulator 200B, and a second frequency generator 300B. The baseband processing circuit 100B, the direct modulator 200B, and the second frequency generator 300B are disposed on the circuit board. An output end of the baseband processing circuit 100B is coupled to a first input end of the direct modulator 200B. An output end of the second frequency generator 300B is coupled to a second input end of the direct modulator 200B. The baseband processing circuit 100B is configured to output a second data signal in the digital signal form, where the second data signal includes at least one bit. The second frequency generator 300B is configured to output a radio electromagnetic wave signal. The direct modulator 200B is configured to perform phase modulation on the radio electromagnetic wave signal based on the second data signal, to obtain a wireless communication signal. A phase of the wireless communication signal indicates a value of the at least one bit of the second data signal.

In some possible implementations, the direct modulator 200B may use a first modulator. As shown in FIG. 3, the first modulator 210B includes a transistor FET1, a microstrip metal wire CL, an intermediate medium J1, and a ground metal plate G1. The ground metal plate G1 is coupled to a second surface of the intermediate medium J1, and the microstrip metal wire CL is coupled to a first surface of the intermediate medium J1. The first surface and the second surface are two opposite surfaces of the intermediate medium J1. The microstrip metal wire CL, the intermediate medium J1, and the ground metal plate G1 form a microstrip transmission line structure. A first end of the microstrip metal wire CL is used as a second input end of the first modulator 210B and is coupled to the second frequency generator 300B, and the first end of the microstrip metal wire CL is further used as an output end of the first modulator 210B. A first electrode of the transistor FET l is grounded and a second electrode of the transistor FET1 are coupled to a second end of the microstrip metal wire CL. A gate of the transistor FET1 is used as a first input end of the first modulator 210B and is coupled to the output end of the baseband processing circuit 100B.

For example, as shown in FIG. 3, the second frequency generator 300B outputs the radio electromagnetic wave signal to the first end of the microstrip metal wire CL, and the radio electromagnetic wave signal is transmitted from the first end of the microstrip metal wire CL to the second end of the microstrip metal wire CL. The baseband processing circuit 100B outputs a second data signal of 1 bit to the gate of the transistor FET1. In the process, when the second data signal is at a first level (for example, 1), the first electrode and the second electrode of the transistor FET1 are turned on. When the second data signal is at a second level (for example, 0), the first electrode and the second electrode of the transistor FET1 are turned off. In two cases in which the first electrode and the second electrode of the transistor FET1 are turned on and turned off, reflection of the radio electromagnetic wave signal transmitted by the microstrip metal wire CL may be separately implemented based on different reflection coefficients (in other words, the radio electromagnetic wave signal at the second end of the microstrip metal wire CL is reflected back to the first end of the microstrip metal wire CL), and the reflection coefficients in the two cases are respectively −1 and 1 (representing that a phase difference between the corresponding reflected radio electromagnetic wave signals in the two cases is 180°). Further, the reflected radio electromagnetic wave signal output by the first end of the microstrip metal wire CL is used as a phase-modulated wireless communication signal. A phase of the wireless communication signal may indicate a value of the second data signal of 1 bit. An example in which a phase of a radio electromagnetic wave signal input by the first modulator 210B is 0° is used. When the reflection coefficient is −1, a wireless communication signal (whose phase is 0°) corresponding to a second data signal whose value is 1 is obtained. When the reflection coefficient is 1, a wireless communication signal (whose phase is −180°) corresponding to a second data signal whose value is 0 is obtained.

In this embodiment of this application, turn-on and turn-off of the transistor FET1 may be controlled by using the second data signal in the digital signal form, to perform reflective phase modulation on the radio electromagnetic wave signal. However, a cut-off frequency of the transistor FET1 is high, and when a band of the radio electromagnetic wave signal and a band of the wireless communication signal reach the terahertz band and above, a phase modulation effect is poor. A cut-off frequency of a diode is lower than the cut-off frequency of the transistor FET1, and the diode is more applicable to a device that is in the first modulator 210B and that is used to control a reflection coefficient. However, a parasitic capacitor of the diode is different from that of the transistor FET1. It is difficult for the diode to perform transmission impedance matching with the microstrip metal wire CL of the first modulator 210B. This limits application of the diode in the first modulator 210B.

For example, the direct modulator 200B shown in FIG. 2 may use a second modulator.

In some possible implementations, the second modulator includes a first modulation circuit. As shown in FIG. 4, the first modulation circuit B1 includes a diode D1 and a first microstrip. The first microstrip includes a first metal wire CL1, a first spacing area I1, a second metal wire CL2, an intermediate medium J1, and a ground metal plate G1. As shown in FIG. 4 and FIG. 6, the ground metal plate G1 is coupled to a second surface of the intermediate medium J1, the first metal wire CL1 and the second metal wire CL2 are disposed in parallel on a first surface of the intermediate medium J1 along a first straight line L1, and the first surface and the second surface are two opposite surfaces of the intermediate medium J1. A first end of the first metal wire CL1 is opposite to a second end of the second metal wire CL2, and a first spacing area I1 with a spacing distance equal to a first value W1 exists between the first end of the first metal wire CL1 and the second end of the second metal wire CL2. A second end of the first metal wire CL1 is coupled to an anode of the diode D1. The anode of the diode D1 is further used as a first input end of the first modulation circuit B1 and is coupled to the output end of the baseband processing circuit 100B. A first end of the second metal wire CL2 is used as a second input end of the first modulation circuit B1 and is coupled to the second frequency generator 300B, and the first end of the second metal wire CL2 is further used as an output end of the first modulation circuit B1.

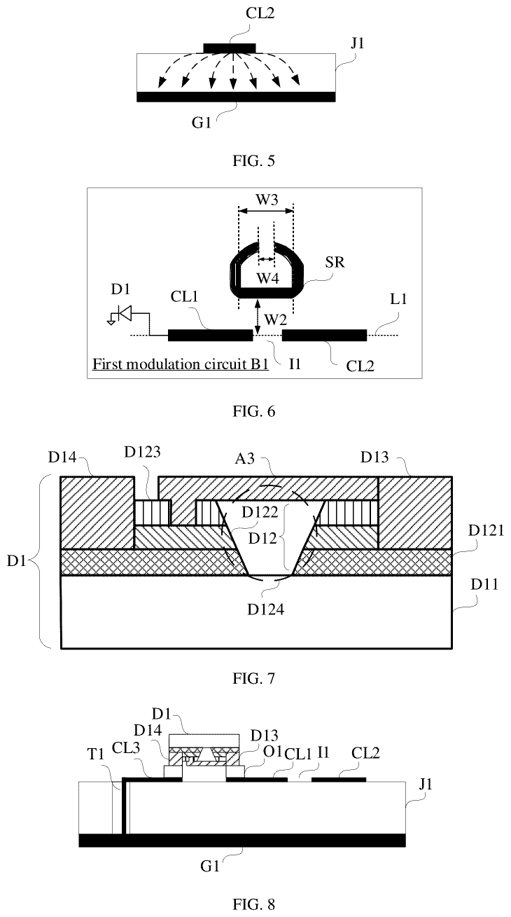

For example, a structure shown in FIG. 4 is used as a main view of the first microstrip. FIG. 5 is a schematic right-side sectional view of the first microstrip. As shown in FIG. 5, the second metal wire CL2 and the first metal wire CL1 (not shown in FIG. 5) are on the first surface of the intermediate medium J1, and are exposed in space. When a radio electromagnetic wave signal is transmitted on the second metal wire CL2 and the first metal wire CL1, the second metal wire CL2 and the first metal wire CL1 each form an equivalent capacitance structure with the ground metal plate G1, an electric field is transmitted from the second metal wire CL2 and the first metal wire CL1 to the ground metal plate G1, and most electrons of the electric field are constrained in the intermediate medium J1.

For example, as shown in FIG. 6, due to factors such as processing process precision, there is a processing error between the first metal wire CL1 and the second metal wire CL2. When the first metal wire CL1 and the second metal wire CL2 are kept parallel to the first straight line L1 within a first error range, it may be considered that the first metal wire CL1 and the second metal wire CL2 are disposed in parallel along the first straight line L1.

In the embodiment shown in FIG. 3, in a scenario in which the radio electromagnetic wave signal is transmitted through the microstrip metal wire CL, it is difficult to implement transmission matching between the microstrip metal wire CL and the diode. In the embodiment shown in FIG. 4 of this application, the first metal wire CL1 and the second metal wire CL2 may form the first spacing area I1. The first spacing area I1 is equivalent to a truncated structure obtained by truncating a middle section of the microstrip metal wire CL in FIG. 3. In this embodiment of this application, the first end of the second metal wire CL2 is used as the second input end of the first modulation circuit B1, and the radio electromagnetic wave signal is input from the second frequency generator 300B. The radio electromagnetic wave signal is transmitted from the first end of the second metal wire CL2 to the second end of the second metal wire CL2, is transmitted to the first end of the first metal wire CL1 through the first spacing area I1, and then is transmitted from the second end of the first metal wire CL1 to the anode of the diode D1. The anode of the diode D1 is used as the first input end of the first modulation circuit B1, and the second data signal of 1 bit is obtained from the baseband processing circuit 100B. A level value of the second data signal corresponds to a data value of the second data signal of 1 bit. According to a change of a value of the second data signal, the diode D1 changes a reflection coefficient of the first microstrip, so that the radio electromagnetic wave signal reflected from the second end of the first metal wire CL1 to the first end of the second metal wire CL2 has a corresponding phase (in other words, modulation of the input radio electromagnetic wave signal is completed). The wireless communication signal (that is, a phase-modulated radio electromagnetic wave signal) is output through the first end of the second metal wire CL2. A plurality of phases of an output wireless communication signal may indicate a plurality of values of a second data signal of 1 bit output by the baseband processing circuit 100B. During phase modulation, the first spacing area I1 between the first metal wire CL1 and the second metal wire CL2 may be considered as an admittance structure, and is used for transmission matching between the first microstrip and the diode D1. Similarly, the first spacing area I1 between the first end of the first metal wire CL1 and the second end of the second metal wire CL2 may alternatively be considered as an equivalent capacitance. An equivalent capacitance structure formed by the first spacing area I1 may adjust transmission impedance between a first transmission line and the diode D1, to implement transmission impedance matching.

In the embodiment shown in FIG. 4, the first spacing area I1 also enables a strong reflection structure to be formed between the first metal wire CL1 and the second metal wire CL2. The strong reflection structure may enable matching between the first microstrip and the diode D1, but also represents that a stronger reflection effect occurs during transmission of the radio electromagnetic wave signal between the first end of the first metal wire CL1 and the second end of the second metal wire CL2. The reflection effect produces more reflected waves. These reflected waves will interfere with each other. In this way, only a radio electromagnetic wave signal with a specific frequency may implement the foregoing phase modulation and transmission. A spacing degree of the first spacing area I1 may be adjusted based on a transmission band and a parameter of the diode D1, to implement transmission matching between the diode D1 and the first microstrip. However, in this embodiment of this application, the strong reflection structure formed by the first spacing area I1 also enables a tolerance of the parasitic capacitor of the diode D1 to become worse. These problems also limit application of the first modulation circuit B1 in a large-bandwidth scenario to some extent.

In some possible implementations, the first modulation circuit B1 in the embodiment shown in FIG. 4 may further include a metal resonant ring. As shown in FIG. 6, the metal resonant ring SR is disposed on the first surface of the intermediate medium J1, and is located on a side that is of the first spacing area I1 and that is relative to the first metal wire CL1 and the second metal wire CL2. A vertical shortest distance between the metal resonant ring SR and the first spacing area I1 relative to the first straight line L1 is a second value W2. In this embodiment of this application, the metal resonant ring SR that may be equivalent to an inductor is disposed, and is combined with the first spacing area I1 that is equivalent to a capacitor, so that the transmission impedance may be further adjusted based on the first spacing area I1, and a broadband matching range of a phase modulation structure of the diode D1 with the first microstrip is larger.

In some possible implementations, a parameter of the metal resonant ring SR is adjusted, so that a transmission bandwidth of the first modulation circuit B1 may be adjusted based on transmission impedance matching.

In a possible implementation, the transmission impedance matching may be adjusted by adjusting a coupling degree between the metal resonant ring SR and the first spacing area I1.

For example, as shown in FIG. 6, the metal resonant ring SR includes a first ring segment with a length of a third value W3. The first ring segment and the first straight line L1 maintain the vertical shortest distance of the second value W2. In this embodiment of this application, the vertical shortest distance between the metal resonant ring SR and the first straight line L1 represents a relative distance between the metal wire resonant ring SR and the first spacing area I1. The relative distance represents the coupling degree between the metal resonant ring SR and the first spacing area I1. Similarly, a longer vertical shortest distance between the metal resonant ring SR and the first straight line L1 indicates a stronger coupling degree between the metal resonant ring SR and the first spacing area I1. The coupling degree between the metal resonant ring SR and the first spacing area I1 may be adjusted by adjusting the length of the first ring segment (that is, a value of the third value W3).

For example, as shown in FIG. 6, a connection line between a midpoint of the metal resonant ring SR and a midpoint of the first spacing area I1 is perpendicular to the first straight line L1. In this embodiment of this application, the connection line between the midpoint of the metal resonant ring SR and the midpoint of the first spacing area I1 is set to be perpendicular to the first straight line L1, so that a better coupling strength between the metal resonant ring SR and the first spacing area I1 may be implemented under a same condition.

In a possible implementation, the transmission impedance matching may be further adjusted by adjusting an equivalent inductance value of the metal resonant ring SR.

For example, as shown in FIG. 6, an open slot is provided on a side that is of the metal resonant ring SR and that is away from the first metal wire CL1 and the second metal wire CL2, and a slot spacing of the open slot is a fourth value W4. In this embodiment of this application, the slot spacing (that is, the fourth value W4) of the open slot is adjusted, so that a response frequency of the metal resonant ring SR may be adjusted to adjust an impedance capacitance value of the metal resonant ring SR, to implement adjustment on the transmission bandwidth matching of the first modulation circuit B1. The open slot is a slot structure formed by two ends of the open metal resonant ring SR. Due to factors such as processing process precision, the two ends of the metal resonant ring SR may not be uniform straight-line ports. During actual application, a shortest straight-line distance between the two ends of the metal resonant ring SR may be used as the fourth value W4; a longest straight-line distance between the two ends of the metal resonant ring SR may be used as the fourth value W4; or an average straight-line distance between the two ends of the metal resonant ring SR may be used as the fourth value W4. This is not specifically limited in this embodiment of this application.

In the embodiments shown in FIG. 4 and FIG. 6, specific values of the first value W1, the second value W2, the third value W3, and the fourth value W4 may be adjusted based on an actual device parameter of the diode D1, a frequency value of a radio electromagnetic wave signal that needs to be transmitted, and the like.

In some possible implementations, the diode D1 and the first microstrip in the first modulation circuit B1 are processed separately and independently, and are coupled through a metal lead. In this embodiment of this application, the diode D1 and the first microstrip are separately processed by using different processes. Then, the diode D1 is electrically connected to the first microstrip based on the metal lead.

In some possible implementations, the diode D1 in the first modulation circuit B1 is processed on the first microstrip. In this embodiment of this application, the diode D1 may be processed on the first microstrip, to improve integration of the direct modulator 200B, and the like.

For example, FIG. 7 is a diagram of a structure of a Schottky diode based on gallium arsenide (gallium arsenide, GaAs). The diode D1 shown in FIG. 7 includes a gallium arsenide substrate D11 and a body D12 of the diode D1 that are sequentially stacked from bottom to top. The diode D1 further includes an anode D13, a cathode D14, and a third air bridge A3. The body D12 includes a buffer layer D121, an epitaxial layer D122, and a passivation layer D123 that are sequentially stacked from bottom to top. The cathode D14 of the diode D1 and the anode D13 of the diode D1 are respectively grown on two sides of an upper end surface of the buffer layer D121, positioned on opposite sides of the epitaxial layer D122 and the passivation layer D123. Optionally, the buffer layer D121 is a heavily doped gallium arsenide medium layer, the epitaxial layer D122 is a lightly doped gallium arsenide medium layer, and the passivation layer D123 is a silicon dioxide layer. A vacant slot D124 is provided in a middle section of the buffer layer D121, the epitaxial layer D122, and the passivation layer D123 on the body D12. A first end of the third air bridge A3 is coupled to the anode D13 of the diode D1. A second end of the third air bridge A3 is coupled to the passivation layer D123 on a side of the cathode D14 of the diode D1 across the vacant slot D124.

In a possible implementation, the diode D1 is invertedly coupled to the first microstrip. As shown in FIG. 4, FIG. 6, and FIG. 8, the first microstrip further includes the ground metal plate G1 and a third metal wire CL3. As shown in FIG. 8, a through hole T1 running through the first surface and the second surface is provided on the intermediate medium J1. A second end of the third metal wire CL3 penetrates into the through hole T1 from the first surface and is coupled to the ground metal plate G1, to implement grounding of the diode D1. The cathode D14 of the diode D1 is coupled to a first end of the third metal wire CL3. In this embodiment of this application, the diode D1 and the first microstrip may be processed separately and independently, and then the diode D1 is invertedly sintered (sintered) on the first microstrip. The anode D13 of the diode D1 is sintered and coupled to the first metal wire CL1 of the first microstrip. The cathode D14 of the diode D1 is coupled to the third metal wire CL3 of the first microstrip.

For example, in the embodiment shown in FIG. 8, in a process in which the diode D1 is invertedly sintered on the first microstrip, the anode D13 and the cathode D14 of the diode D1 may be electrically connected to the first microstrip by using a conductive material. For example, the conductive material may be an epoxy conductive material O1.

In the implementation shown in FIG. 8 in this embodiment of this application, when the radio electromagnetic wave signal and the wireless communication signal are in a band below the terahertz band, substrate materials of the diode D1 and the first microstrip are not limited. When the radio electromagnetic wave signal and the wireless communication signal are at the terahertz band, for example, the diode D1 may be a diode based on a gallium arsenide material (for example, a diode having the structure shown in FIG. 7), and the intermediate medium J1 of the first microstrip may be a quartz material, a gallium arsenide material, or the like.

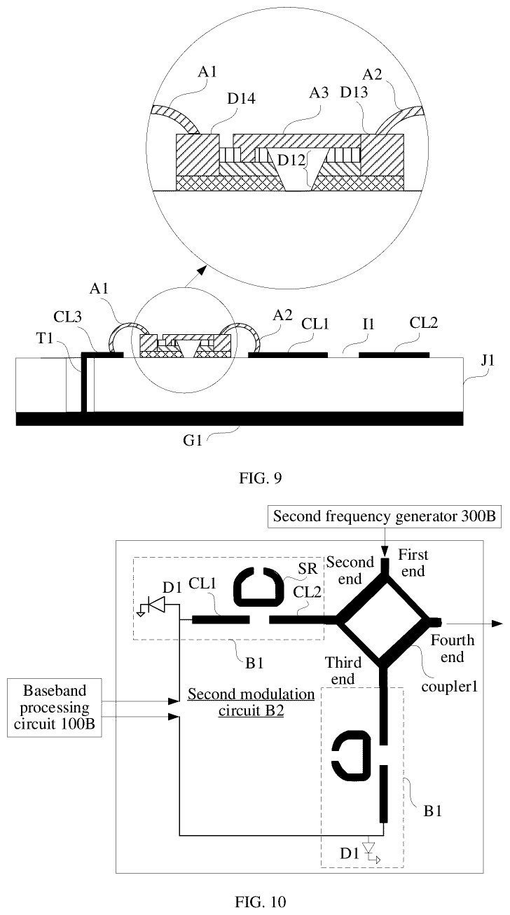

Optionally, the diode D1 is coupled in a non-flipped orientation to the first microstrip. For example, the diode D1 and the first microstrip in the first modulation circuit B1 are processed simultaneously. In this case, the intermediate medium J1 of the first microstrip and the substrate D11 of the diode D1 may be of a same dielectric material. As shown in FIG. 9, the first microstrip shown in FIG. 4 and FIG. 6 further includes a third metal wire CL3, a first air bridge A1, and a second air bridge A2. A through hole T1 running through the first surface and the second surface is provided on the intermediate medium J1. A second end of the third metal wire CL3 penetrates into the through hole T1 from the first surface and is coupled to the ground metal plate G1, to implement grounding of the diode D1. A body D12 of the diode D1 is formed the first surface, a cathode D14 of the diode D1 is coupled to a first end of the third metal wire CL3 through the first air bridge A1, and an anode D13 of the diode D1 is coupled to the second end of the first metal wire CL1 through the second air bridge A2.

For example, when phase modulation is performed on the radio electromagnetic wave signal at the terahertz band, in the embodiment shown in FIG. 9, the intermediate medium J1 may be a gallium arsenide medium. The diode D1 is also a diode based on a gallium arsenide material. In this embodiment of this application, when the diode D1 is disposed on the first microstrip based on a same processing operation, the intermediate medium J1 of the first microstrip may be used as the gallium arsenide substrate D11 of the diode D1 shown in FIG. 7. In this case, as shown in FIG. 9, the body D12 of the diode D1 shown in FIG. 7 is grown on the intermediate medium J1. Then, the anode D13 of the diode D1 is electrically connected to the second metal wire CL2 of the first microstrip through the first air bridge A1. The cathode D14 of the diode D1 is electrically connected to the third metal wire CL3 of the first microstrip through the second air bridge A2. The diode D1 is coupled to the ground metal plate G1 of the first microstrip through the third metal wire CL3, to implement grounding of the diode D1.

In some possible implementations, the direct modulator 200B shown in FIG. 2 may use a second modulation circuit. As shown in FIG. 10, the second modulation circuit B2 includes a first coupler coupler1 and two first modulation circuits B1. A second end of the first coupler coupler1 is a through end relative to a first end of the first coupler coupler1, and a third end of the first coupler coupler1 is a coupling end relative to the first end of the first coupler coupler1. The second end and the third end of the first coupler coupler1 are respectively coupled, via first coupling, a corresponding first modulation circuit B1. The first coupling refers to coupling the corresponding first coupler coupler1 via the first end of the second metal wire CL2 of the first modulation circuit B1. A first output end and a second output end of the baseband processing circuit 100B are coupled to anodes of diodes D1 in the two first modulation circuits B1, respectively and correspondingly.

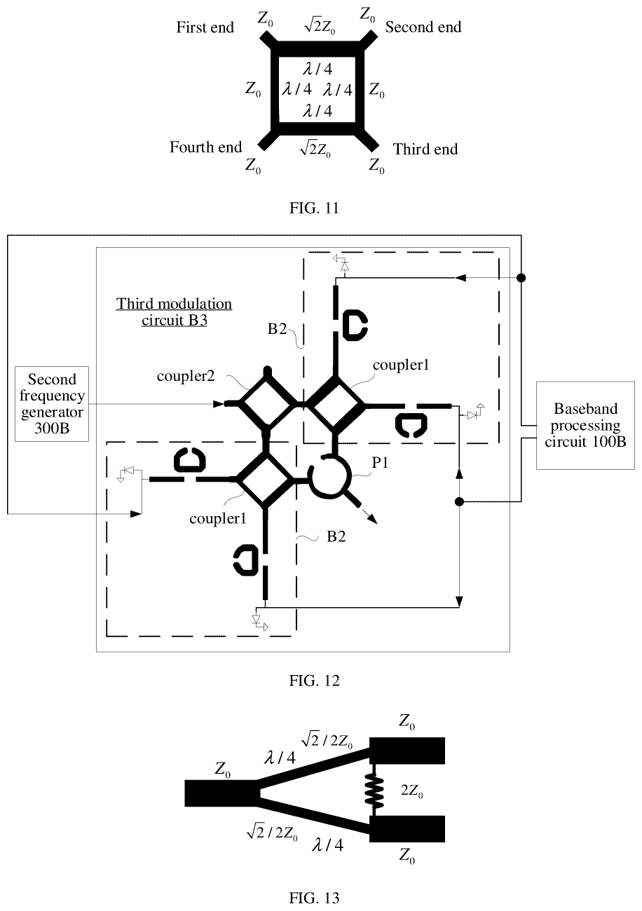

For example, FIG. 11 shows an implementation structure of a coupler. The coupler includes two through paths and two coupling paths. A through path is between a first end and a second end of the coupler, a through path is between a third end and a fourth end, a coupling path is between the first end and the fourth end, and a coupling path is between the second end and the third end. Two ends corresponding to a same coupling path are mutually isolation ends. Two ends corresponding to a same through path are mutually through ends. Two ends corresponding to different through paths and different coupling paths are mutually coupling ends. The coupler shown in FIG. 11 is a device that may implement splitting. After a radio electromagnetic wave signal is input to an input end (any end) of the coupler, a through end and a coupling end corresponding to the input end output two radio electromagnetic wave signals with a specific phase difference (for example, a radio electromagnetic wave signal with a first phase and a radio electromagnetic wave signal with a second phase).

Optionally, in some couplers, radio electromagnetic wave signals between two ends corresponding to a same through path have a specific phase difference based on different setting parameters of the couplers. In some couplers, phases of the radio electromagnetic wave signals between the two ends corresponding to the same through path are the same. However, no matter how a parameter of the coupler is set, there is a specific phase difference between the coupling end and the through end of the coupler.

For example, FIG. 11 shows a coupler whose phases between the two ends corresponding to the same through path are the same. The coupler is of a microstrip-based structure. In this embodiment, the microstrip in the figure includes two through paths whose impedances are Z₀/\sqrt{2} and whose lengths are λ/4 and two coupling paths whose impedances are Z₀ and whose lengths are λ/4. Impedances of the four ports of the coupler are Z₀. Z₀ is a system transmission impedance value. An example in which the first end is an input end of the coupler is used. The second end is a through end relative to the first end. A phase of a radio electromagnetic wave signal output by the through end is the same as a phase of a radio electromagnetic wave signal input by the input end. The third end is a coupling end relative to the first end. A phase difference of 90° exists between a radio electromagnetic wave signal output by the coupling end and the radio electromagnetic wave signal input by the input end. The fourth end is an isolation end relative to the first end. When the input end inputs the radio electromagnetic wave signal, the isolation end does not output the radio electromagnetic wave signal.

In the embodiment shown in FIG. 10 of this application, second input ends (that is, first ends of second metal wires CL2) of the two first modulation circuits B1 are respectively coupled to the through end and the coupling end of the first coupler coupler1, so that radio electromagnetic wave signals with different phases may be respectively input into the second input ends (that is, the first ends of the second metal wires CL2) of the two first modulation circuits B1 via the first coupler coupler1. An example in which a radio electromagnetic wave signal with a first phase is input from the first end of the first coupler coupler1 is used. The radio electromagnetic wave signal with a first phase may be output from the second end of the first coupler coupler1, and a radio electromagnetic wave signal with a second phase may be output from the third end of the first coupler coupler1. After the corresponding first modulation circuit B1 performs phase modulation on the radio electromagnetic wave signal with the first phase, a first phase-modulated signal is obtained. The first phase-modulated signal is input from the second end of the first coupler coupler1 into the first coupler coupler1. The input first phase-modulated signal is not input into an isolation end (that is, the third end of the first coupler coupler1) corresponding to the first coupler coupler1 for output, and is output from a fourth end (a coupling end relative to the second end of the first coupler coupler1) of the first coupler coupler1 after phase shift. Similarly, after the radio electromagnetic wave signal with a second phase is output from the third end of the first coupler coupler to the corresponding first modulation circuit B1, a second phase-modulated signal is obtained after phase modulation performed by the corresponding first modulation circuit B1. The second phase-modulated signal is input into the first coupler coupler1 from the third end of the first coupler coupler1, and then is output from the fourth end (a through end relative to the third end of the first coupler coupler1) of the first coupler coupler1.

Optionally, in the embodiment shown in FIG. 10, the first output end and the second output end of the baseband processing circuit 100B may output a same control voltage signal to indicate data of the second data signal of 1 bit. The first output end and the second output end of the baseband processing circuit 100B may alternatively output different control voltage signals to correspond to data of a second data signal of two different bits. For working principles of phase modulation on the two first modulation circuits B1 in the embodiment shown in FIG. 10, refer to related descriptions in the embodiments shown in FIG. 4, FIG. 6, FIG. 7, FIG. 8, and FIG. 9. Details are not described herein again.

In some possible implementations, the direct modulator 200B shown in FIG. 2 may use a third modulation circuit. As shown in FIG. 12, the third modulation circuit B3 includes a second coupler coupler2, a power combiner P1, and two second modulation circuits B2. A second end of the second coupler coupler2 is a through end relative to a first end of the second coupler coupler2, a third end of the second coupler coupler2 is a coupling end relative to the first end of the second coupler coupler2, and a fourth end of the first coupler coupler1 is an isolation end relative to the first end of the first coupler coupler1. The second end and the third end of the second coupler coupler2 are respectively coupled, via second coupling, to a first coupler coupler1 in the second modulation circuit B2. The second coupling refers to coupling the second coupler coupler2 via the first end of the first coupler coupler1 in the second modulation circuit B2. A first input end and a second input end of the power combiner P1 are respectively coupled, via third coupling, the first coupler coupler1 in the second modulation circuit B2. The third coupling refers to coupling the power combiner P1 via the fourth end of the first coupler coupler1 in the second modulation circuit B2. A first output end of the baseband processing circuit 100B is separately coupled to anodes of two first diodes. The two first diodes are diodes D1 corresponding to a first modulation circuit B1 coupled to second ends of two first couplers coupler1. A second output end of the baseband processing circuit 100B is separately coupled to anodes of two second diodes. The two second diodes are diodes D1 corresponding to a first modulation circuit B1 coupled to third ends of the two first couplers coupler1.

For example, a through end of the second coupler coupler2 outputs an in-phase signal. In the embodiment shown in FIG. 12 of this application, after a radio electromagnetic wave signal is input to the first end of the second coupler coupler2, an I wireless communication signal and a Q wireless communication signal may be respectively output from the second end of the second coupler coupler2 and the third end of the second coupler coupler2. The I wireless communication signal is a radio electromagnetic wave signal whose phase is the same as that of the input radio electromagnetic wave signal, and the Q wireless communication signal is a radio electromagnetic wave signal orthogonal to the input radio electromagnetic wave signal (in other words, a phase difference is 90°). After the I wireless communication signal is input from the first end of the first coupler coupler1 in the corresponding second modulation circuit B2, an I second modulation circuit B2 is controlled to perform phase modulation by using a second data signal of 2 bits that is output by the first output end and the second output end of the baseband processing circuit 100B, and then a phase-modulated I wireless communication signal is output to the first input end of the power combiner P1. In addition, after the Q wireless communication signal is input from the first end of the first coupler coupler1 in the corresponding second modulation circuit B2, a Q second modulation circuit B2 is controlled to perform phase modulation by using the second data signal of 2 bits that is output by the first output end and the second output end of the baseband processing circuit 100B, and then a phase-modulated Q wireless communication signal is output to a second input end of the power combiner P1. After the power combiner P1 combines the I wireless communication signal and the Q wireless communication signal, a wireless communication signal is output from an output end of the power combiner P1.

For example, FIG. 13 is a diagram of a Wilkinson power combiner of a microstrip-based structure. The Wilkinson power combiner includes two power division paths whose impedances are \sqrt{2}/2Z₀ and lengths are λ/4. Impedances of a first input end, a second input end, and an output end of the Wilkinson power combiner are system transmission impedances Z₀. The first input end and the second input end of the Wilkinson power combiner are separately coupled to the output end of the Wilkinson power combiner through the power division paths. In addition, an absorption resistor R with 2Z₀ resistances is further coupled between the first input end and the second input end of the Wilkinson power combiner. In this embodiment of this application, the I wireless communication signal and the Q wireless communication signal may be combined with equal power by using the two power division paths. The absorption resistor R may absorb mismatched reflected waves at the first input end and the second input end of the Wilkinson power combiner.

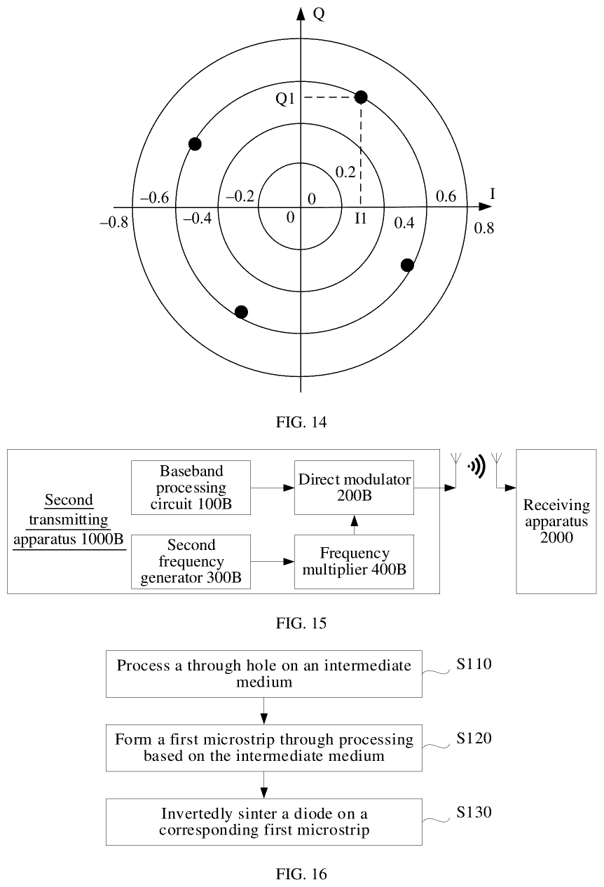

In the embodiment shown in FIG. 12 of this application, the third modulation circuit B3 may perform, based on the second data signals with two bits that are output by the first output end and the second output end of the baseband processing circuit 100B, QPSK modulation on the radio electromagnetic wave signal input by the first end of the second coupler coupler2. During QPSK modulation performed by the third modulation circuit B3, after vector superposition is implemented, by the power combiner P1, on a modulated I wireless communication signal and a modulated Q wireless communication signal, a final wireless communication signal is output from the output end of the power combiner P1. As shown in FIG. 14, based on a difference between the I wireless communication signal and the Q wireless communication signal, the third modulation circuit B3 may obtain a QPSK modulated constellation diagram corresponding to four quadrants after vector superposition. The four quadrants in the figure are respectively corresponding to four values of the second data signal: 00, 01, 10, and 11. Because each modulation symbol may carry two bits, that is, 2^{m}=4 and m=2, the constellation diagram shown in FIG. 14 may include four constellation points, and each constellation point may carry data information with two bits. A constellation point in an upper right corner in FIG. 14 is used as an example. I1 is coordinates of the constellation point on an I-axis (that is, a value of the constellation point projected on the I-axis), and represents phase information of an I component in the modulation symbol. Q1 is coordinates of the constellation point on a Q-axis (that is, a value of the constellation point projected on the Q-axis), and represents phase information of a Q component in the modulation symbol. During actual application, a receiving side may obtain, through demodulation based on a correspondence between wireless communication signals on the QPSK modulated constellation diagram, a value of a second data signal of 2 bits carried in the radio electromagnetic wave signal.

For example, the third modulation circuit B3 shown in FIG. 12 may be further used in QAM modulation. The QAM modulation means to transfer information based on an amplitude change and a phase change of a radio electromagnetic wave signal, and maintain a frequency of the radio electromagnetic wave signal unchanged. In other words, based on the QPSK modulation, amplitude information and phase information of the radio electromagnetic wave signal are modulated, and finally a wireless communication signal with an amplitude change and a phase change is obtained.

In some possible implementations, when the direct modulation circuit 200B in the second transmitting apparatus 1000B shown in FIG. 2 is a modulation circuit based on at least one of the structures in FIG. 4, FIG. 6, FIG. 8, FIG. 9, FIG. 10, and FIG. 12, as shown in FIG. 15, the second transmitting apparatus 1000B further includes a frequency multiplier 400B. The output end of the second frequency generator 300B is coupled to the second input end of the direct modulator 200B through the frequency multiplier 400B. In this embodiment of this application, when the direct modulation circuit 200B with a direct modulated architecture is used, the direct modulation circuit 200B may be driven by using a high-power frequency multiplier 400B, to improve signal power and coverage of a wireless communication signal output by the direct modulation circuit 200B. In this embodiment of this application, a wireless communication signal with high power can be output without a need to dispose the first power amplifier 500A in the architecture shown in FIG. 1, to avoid a problem that it is difficult for a wireless communication signal with a high band to match an appropriate power amplification device.

In some possible implementations, the second transmitting apparatus 1000B shown in FIG. 2 further includes a second power amplifier. For example, the second power amplifier may be coupled to a front end of a first input end of the direct modulation circuit 200B, or may be coupled to a back end of an output end of the direct modulation circuit 200B. In the foregoing embodiments, when the architecture shown in FIG. 1 is used in a high band (for example, a terahertz band), it is difficult to match an applicable power amplification device. However, the descriptions in the foregoing embodiments should not be considered as a limitation on application of the power amplification device in the second transmitting apparatus 1000B shown in FIG. 2. In the direct modulated architecture shown in FIG. 2, the frequency multiplier 400B shown in FIG. 15 may be used to drive the direct modulation circuit 200B, to increase signal power of an output wireless communication signal. In this embodiment of this application, when the second transmitting apparatus 1000B shown in FIG. 2 may match an applicable power amplification device, an adapted second power amplifier may be used to increase signal power of an output wireless communication signal.

When the direct modulator 200B shown in FIG. 2 includes the structures shown in FIG. 4, FIG. 6, FIG. 7, FIG. 10, FIG. 11, FIG. 12, and FIG. 13, and is used in the structure shown in FIG. 8, an embodiment of this application provides a manufacturing method, for manufacturing the direct modulator 200B based on the structures shown in FIG. 4, FIG. 6, FIG. 7, FIG. 8, FIG. 10, FIG. 11, FIG. 12, and FIG. 13. For example, the manufacturing method includes the following steps S110 to S130 shown in FIG. 16.

S110: Process a through hole T1 on an intermediate medium J1.

For example, the intermediate medium J1 may be a quartz medium, a gallium arsenide medium, or the like.

For example, the intermediate medium J1 may be a medium corresponding to manufacturing of one or more first modulation circuits B1 shown in FIG. 4 and FIG. 6, the intermediate medium J1 may be a medium corresponding to manufacturing of one or more second modulation circuits B2 shown in FIG. 10, or the intermediate medium J1 may be a medium corresponding to manufacturing of one or more third modulation circuits B3 shown in FIG. 12.

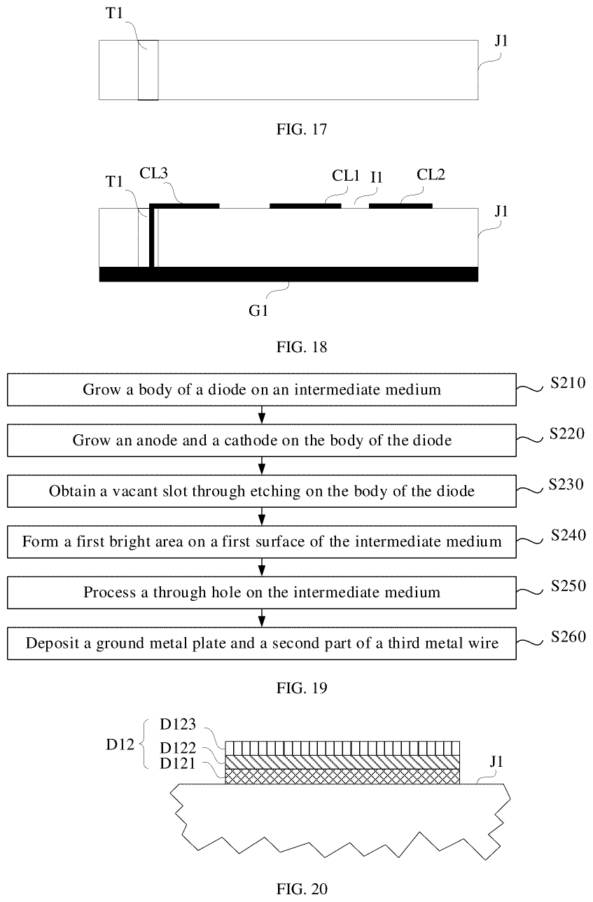

An example in which the first modulation circuit B1 shown in FIG. 4 and FIG. 6 is processed is used. As shown in FIG. 17, a through hole T1 is polished on the intermediate medium J1, and the through hole T1 is used for subsequently implementing grounding connection of a diode D1. For descriptions of polishing the through hole T1 in the embodiments shown in FIG. 10 and FIG. 12, refer to related descriptions in the embodiment shown in FIG. 17. Details are not described herein again.

S120: Process based on the intermediate medium J1 to form a first microstrip.

In some possible implementations, when the first modulation circuit B1 shown in FIG. 4 is generated, as shown in FIG. 18, a first bright area is formed on a first surface of the intermediate medium J1 based on photoresist by using a mask (mask), and a first metal wire CL1, a second metal wire CL2, and a third metal wire CL3 are etched (etched) on the first surface of the intermediate medium J1 by using the first bright area.

For example, when the first modulation circuit B1 shown in FIG. 6 is generated, a metal resonant ring SR further needs to be obtained through etching based on the first bright area.

For example, when the structures shown in FIG. 10 and FIG. 12 are generated, a metal wire of the first coupler coupler1 further needs to be obtained through etching based on the first bright area. In the structure shown in FIG. 12, a metal wire of the second coupler coupler2 further needs to be obtained through etching based on the first bright area. The first coupler coupler1 and the second coupler coupler2 that are of the structure shown in FIG. 11 and the power combiner P1 that is of the structure shown in FIG. 13 are both microstrip-based structures. Metal wire structures of the two couplers are shown in FIG. 10, FIG. 11, and FIG. 12. A metal wire structure of the power combiner P1 is shown in FIG. 13. Details are not described herein again. For structural processing of the first microstrip of the first modulation circuit B1 in the structures shown in FIG. 10 and FIG. 12, refer to related descriptions in the embodiments in FIG. 4 and FIG. 6. Details are not described herein again.

In some possible implementations, in the structures shown in FIG. 4, FIG. 6, FIG. 10, and FIG. 12, a ground metal plate G1 further needs to be obtained through metal deposition (deposition) on a second surface of the intermediate medium J1. For example, the ground metal plate G1 may be first obtained through metal deposition on the second surface of the intermediate medium J1, and then the first metal wire CL, the second metal wire CL, the third metal wire CL, and the like are obtained through etching based on the first bright area on the first surface of the intermediate medium J1; performing etching processing on the first bright area of the first surface and metal deposition processing on the second surface may be simultaneously performed, or performing metal deposition processing on the second surface first, and then etching processing on the first bright area of the first surface.

For example, during actual processing and manufacturing, etching may be performed multiple times layer by layer based on a plurality of layers of masks (mask), to form a complete first bright area.

For example, when a plurality of direct modulators 200B are simultaneously processed on the intermediate medium J1 in step S110 and step S120, after the operation in step S120 is completed, the intermediate medium J1 further needs to be cut, to obtain microstrip structures of the plurality of direct modulators 200B through cutting. For a microstrip structure of each direct modulator 200B, an operation of the following step S130 is performed.

S130: Invertedly sinter a diode D2 on a corresponding first microstrip.

As shown in FIG. 8, the anode D13 of the diode D1 is coupled to the second end of the first metal wire CL1 by using the epoxy conductive material O1, and the cathode D14 of the diode D1 is coupled to the first end of the third metal wire CL3. In this embodiment of this application, the diode D1 is electrically connected to the first metal wire CL1 and the third metal wire CL3 by using the epoxy conductive material O1 separately.

In this embodiment of this application, the direct modulator 200B based on the structure in FIG. 8 is obtained by using the manufacturing method in step S110 to step S130. In the structure shown in FIG. 8, the first microstrip and the diode D1 are processed separately and independently, and then are sintered and coupled together by using step S130. In the implementation, the direct modulator 200B has low application costs and is easy to maintain.

When the direct modulator 200B shown in FIG. 2 includes the structures shown in FIG. 4, FIG. 6, FIG. 7, FIG. 10, FIG. 11, FIG. 12, and FIG. 13, and is used in the structure shown in FIG. 9, an embodiment of this application further provides a manufacturing method, for manufacturing the direct modulator 200B based on the structures shown in FIG. 4, FIG. 6, FIG. 7, FIG. 9, FIG. 10, FIG. 11, FIG. 12, and FIG. 13. For example, the manufacturing method includes the following steps S210 to S260 shown in FIG. 19.

Step S210: Grow a body D12 of a diode D1 on an intermediate medium J1.

For example, as shown in FIG. 20, a buffer layer D121, an epitaxial layer D122, and a passivation layer D123 that sequentially overlap are grown on the intermediate medium J1.

Step S220: Grow an anode D13 and a cathode D14 on the body D12 of the diode D1.

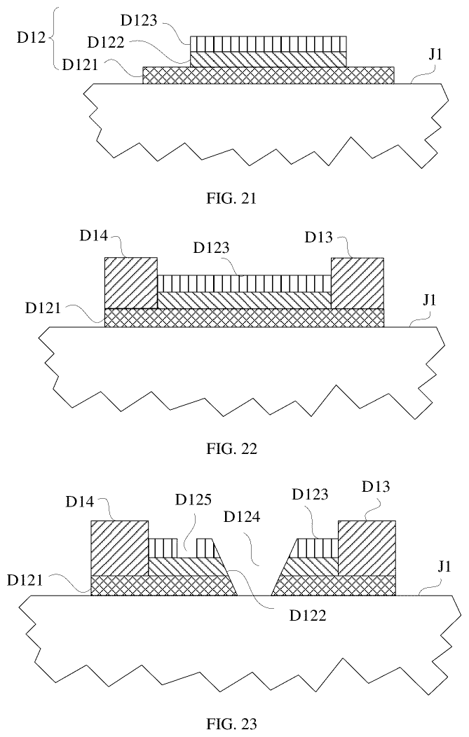

For example, as shown in FIG. 21, the epitaxial layer D122 and the passivation layer D123 on two sides of an upper end of the buffer layer D121 are removed. As shown in FIG. 22, the anode D13 of the diode D1 and the cathode D14 of the diode D1 are respectively deposited on the two sides of the upper end of the buffer layer D121 after the epitaxial layer D122 and the passivation layer D123 are removed.

Step S230: Obtain a vacant slot D124 through etching on the body D12 of the diode D1.

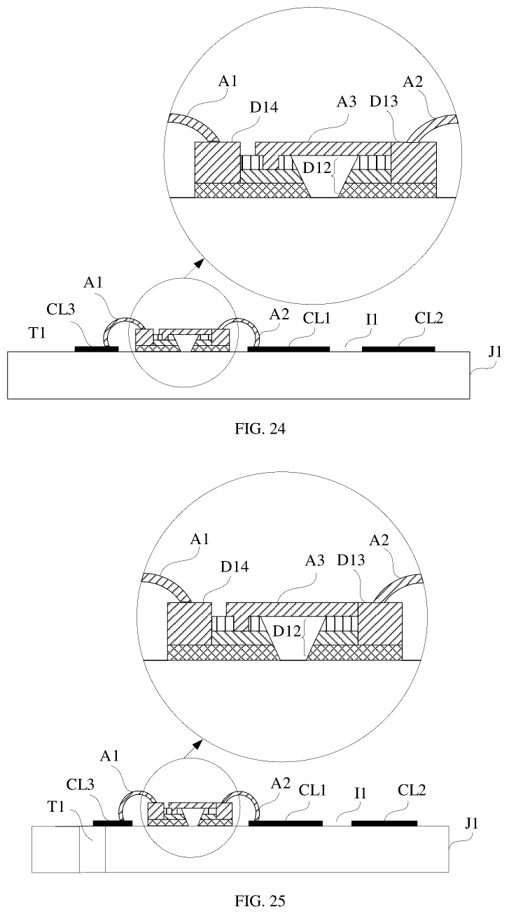

For example, as shown in FIG. 23, after the anode D13 of the diode D1 and the cathode D14 of the diode D1 are deposited, a middle section of the buffer layer D121, the epitaxial layer D122, and the passivation layer D123 are etched to obtain the vacant slot D124.

For example, as shown in FIG. 23, the passivation layer D123 close to the cathode D14 is etched to obtain a notch D125.

Step S240: Form a first bright area on a first surface of the intermediate medium J1.

In some possible implementations, the first bright area is formed on the intermediate medium J1 by using photoresist.

For example, when the structures in the embodiments shown in FIG. 4 and FIG. 9 are processed, as shown in FIG. 24, a first metal wire CL1, a second metal wire CL2, a first air bridge A1, a second air bridge A2, a third air bridge A3, and a first part of a third metal wire CL3 are obtained by etching using the first bright area on a first surface. The first part of the third metal wire CL3 is a part on the first surface, in other words, includes a part at a first end of the third metal wire CL3. In this embodiment of this application, for related descriptions of the metal resonant ring SR, the first coupler coupler1, the second coupler coupler2, and the power combiner P1 that are of the direct modulation circuit 200B and that include the structures shown in FIG. 6, FIG. 10, and FIG. 12 and that are obtained through processing the first bright area, refer to related descriptions of processing the metal resonant ring SR, the first coupler coupler1, the second coupler coupler2, and the power combiner P1 on the first bright area in the embodiment shown in FIG. 18. Details are not described herein again.

Step S250: Process a through hole T1 on the intermediate medium J1.

For example, as shown in FIG. 25, a second surface of the intermediate medium J1 is polished to thin the intermediate medium J1, and then the through hole T1 is polished on the intermediate medium J1.

Step S260: Deposit a ground metal plate G1 and a second part of the third metal wire CL3.

For example, as shown in FIG. 9, the second part of the third metal wire CL3 is deposited in the through hole T1, and the ground metal plate G1 is deposited on the second surface of the intermediate medium J1, so that the cathode D14 of the diode D1 is coupled to the ground metal plate G1 through the third metal wire CL3.

For example, when a plurality of direct modulation circuits 200B are simultaneously processed on the intermediate medium J1 that is used as a substrate, after step S260 is completed, the intermediate medium J1 that is used as a substrate further needs to be cut to obtain an intermediate medium J1 of a plurality of sub-blocks and a direct modulator 200B based on the plurality of sub-block-based intermediate medium J1.

In this embodiment of this application, the direct modulator 200B based on the structure in FIG. 9 is obtained by using the manufacturing method recorded in step S210 to step S260. In the structure shown in FIG. 9, the first microstrip and the diode D1 are processed and manufactured together. In the implementation, the first microstrip and the diode D1 in the direct modulator 200B share the intermediate medium J1 as respective substrates. The structure shown in FIG. 9 can improve performance of the first modulation circuit B1, the second modulation circuit B2, and the third modulation circuit B3.

Embodiments of this application provide a modulator, a manufacturing method, and a transmitting apparatus. The transmitting apparatus includes a frequency generator, a processing circuit, and a modulator. At least one first modulation circuit is disposed in the modulator, and the first modulation circuit includes a first microstrip and a diode. The first microstrip includes a first metal wire and a second metal wire. A first end of the first metal wire is opposite to a second end of the second metal wire, and a first spacing area with a spacing distance equal to a first value exists between the first end of the first metal wire and the second end of the second metal wire. A second end of the first metal wire is coupled to an anode of the diode. An output end of the processing circuit is coupled to the anode of the diode. The frequency generator is coupled to a first end of the second metal wire. In this embodiment of this application, the first modulation circuit obtained by using the first microstrip and the diode is a reflective phase modulation circuit. In comparison with a conventional reflective phase modulation circuit, a transistor is used to control a reflection coefficient. In the foregoing embodiments of this application, a reflection coefficient is controlled by using the diode, and a cut-off frequency of the diode is less than that of the transistor. Therefore, the diode is more applicable to phase modulation of a terahertz band, improving phase modulation precision. During actual application, it is difficult for the diode to form transmission matching with the microstrip. In this embodiment of this application, the first metal wire and the second metal wire form the first spacing area, and the first spacing area may be used as an equivalent capacitance or an admittance structure. Transmission matching between a transmission path formed by the first metal wire and the second metal wire and the diode is implemented by using the first spacing area, resolving a problem that it is difficult for the diode to perform transmission matching with a microstrip structure, so that a diode-based first modulation circuit can be used in the phase modulation of the terahertz band. In addition, in this embodiment of this application, the diode and the first microstrip are combined, so that an electromagnetic wave signal at the terahertz band is directly modulated by using a baseband digital signal. In comparison with a manner in which an analog signal is used to modulate the terahertz band in a conventional architecture, in this embodiment of this application, a digital-to-analog converter is not needed, avoiding a waste of costs and power consumption caused by the digital-to-analog converter in a high band application. In addition, during actual application, a power amplifier is not needed, and a problem that it is difficult to adapt to a power amplifier at a high band such as terahertz is resolved.

An embodiment of this application further provides a chip system. The chip system includes at least one controller and at least one interface circuit. The at least one controller and the at least one interface circuit may be interconnected through a line. The controller is configured to support the chip system in implementing functions or steps in the foregoing method embodiments. The at least one interface circuit may be configured to receive a signal from another apparatus (for example, a communication interface, a baseband processing circuit, a direct modulator, or a frequency generator), or send a signal to another apparatus (for example, a communication interface, a baseband processing circuit, a direct modulator, or a frequency generator). The chip system may include a chip, and may further include another discrete component.

The controller in this embodiment of this application may be a chip. For example, the controller may be a field programmable gate array (field programmable gate array, FPGA), an application-specific integrated chip (application-specific integrated circuit, ASIC), a system on chip (system on chip, SoC), a central processing unit (central processing unit, CPU), a network processor (network processor, NP), a digital signal processor circuit (digital signal processor, DSP), a micro controller unit (micro controller unit, MCU), a programmable logic device (programmable logic device, PLD), or another integrated chip.

It should be understood that sequence numbers of the foregoing processes do not mean execution sequences in various embodiments of this application. The execution sequences of the processes should be determined based on functions and internal logic of the processes, and should not be construed as any limitation on the implementation processes of embodiments of this application.

A person of ordinary skill in the art may be aware that, in combination with the examples described in embodiments disclosed in this specification, modules and algorithm steps may be implemented by electronic hardware or a combination of computer software and electronic hardware. Whether the functions are performed by hardware or software depends on particular applications and design constraint conditions of the technical solutions. A person skilled in the art may use different methods to implement the described functions for each particular application, but it should not be considered that the implementation goes beyond the scope of this application.

It may be clearly understood by a person skilled in the art that, for tease and brevity of description, for a detailed working process of the foregoing system, apparatus, and module, refer to a corresponding process in the foregoing method embodiments. Details are not described herein again.

In several embodiments provided in this application, it should be understood that the disclosed system, apparatus, and method may be implemented in other manners. For example, the described apparatus embodiment is merely an example. For example, the module division is merely logical function division and may be other division during actual implementation. For example, a plurality of modules or components may be combined or integrated into another apparatus, or some features may be ignored or not performed. In addition, the displayed or discussed mutual couplings or direct couplings or communication connections may be implemented through some interfaces. The indirect couplings or communication connections between the apparatuses or modules may be implemented in electronic, mechanical, or other forms.

The modules described as separate parts may or may not be physically separate, and parts displayed as modules may or may not be physical modules, in other words, may be located in one apparatus, or may be distributed on a plurality of apparatuses. Some or all the modules may be selected according to actual needs to achieve the objectives of the solutions of embodiments.

In addition, functional modules in embodiments of this application may be integrated into one apparatus, or each of the modules may exist alone physically, or two or more modules are integrated into one apparatus.

All or some of the foregoing embodiments may be implemented by using software, hardware, firmware, or any combination thereof. When a software program is used to implement embodiments, embodiments may be implemented completely or partially in the form of a computer program product. The computer program product includes one or more computer instructions. When the computer program instructions are loaded and executed on a computer, the procedure or functions in embodiments of this application are all or partially generated. The computer may be a general-purpose computer, a dedicated computer, a computer network, or another programmable apparatus. The computer instructions may be stored in a computer-readable storage medium or may be transmitted from a computer-readable storage medium to another computer-readable storage medium. For example, the computer instructions may be transmitted from a website, computer, server, or data center to another website, computer, server, or data center in a wired (for example, a coaxial cable, an optical fiber, or a digital subscriber line (Digital Subscriber Line, DSL)) or wireless (for example, infrared, radio, or microwave) manner. The computer-readable storage medium may be any usable medium accessible by a computer, or a data storage apparatus, such as a server or a data center, integrating one or more usable media. The usable medium may be a magnetic medium (for example, a floppy disk, a hard disk drive, or a magnetic tape), an optical medium (for example, a DVD), a semiconductor medium (for example, a solid-state drive (solid-state drive, SSD)), or the like.

The transmitting apparatus in embodiments of this application may be an apparatus configured to implement a wireless communication function, for example, a terminal or a chip that may be used in the terminal. The terminal may be UE, an access terminal, a terminal unit, a terminal station, a mobile station, a remote station, a remote terminal, a mobile device, a wireless communication device, a terminal agent, a terminal apparatus, or the like in a 6G network or a future evolved public land mobile network (public land mobile network, PLMN). The access terminal may be a cellular phone, a cordless phone, a session initiation protocol (session initiation protocol, SIP) phone, a wireless local loop (wireless local loop, WLL) station, a personal digital assistant (personal digital assistant, PDA), a handheld device or a computing device having a wireless communication function, another processing device connected to a wireless modem, a vehicle-mounted device, a wearable device, a virtual reality (virtual reality, VR) terminal device, an augmented reality (augmented reality, AR) terminal device, a wireless terminal in industrial control (industrial control), a wireless terminal in self driving (self driving), a wireless terminal in telemedicine (remote medical), a wireless terminal in a smart grid (smart grid), a wireless terminal in transportation safety (transportation safety), a wireless terminal in a smart city (smart city), a wireless terminal in a smart home (smart home), or the like. Optionally, the transmitting apparatus may be mobile or fixed.

In a possible implementation, the transmitting apparatus in embodiments of this application may be a network device that communicates with the terminal device. The network device may include a transmission and reception point (transmission and reception point, TRP), a base station, a remote radio unit (remote radio unit, RRU) or a baseband unit (baseband unit, BBU) (which may also be referred to as a digital unit (digital unit, DU)) of a split base station, a satellite, an uncrewed aerial vehicle, a broadband network service gateway (broadband network gateway, BNG), an aggregation switch, a non-3GPP access device, a relay station, an access point, or the like.

In addition, the base station may be a base transceiver station (base transceiver station, BTS) in a global system for mobile communication (global system for mobile communication, GSM) or code division multiple access (code division multiple access, CDMA) network, an NB (NodeB) in wideband code division multiple access (wideband code division multiple access, WCDMA), an eNB or eNodeB (evolutional NodeB) in LTE, a radio controller in a cloud radio access network (cloud radio access network, CRAN) scenario, or a base station (for example, a next generation NodeB (gNodeB, gNB)) in a 5G communication system, a base station in a future evolved network, or the like. This is not specifically limited herein.

In addition, a communication architecture and a service scenario described in embodiments of this application are intended to describe the technical solutions in embodiments of this application more clearly, and do not constitute a limitation on the technical solutions provided in embodiments of this application. A person of ordinary skill in the art may know that, with the evolution of the communication architecture and the emergence of new service scenarios, the technical solutions provided in embodiments of this application are also applicable to similar technical problems.

The foregoing descriptions are merely specific implementations of this application, but are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

1. A modulator, comprising a first modulation circuit, wherein the first modulation circuit comprises a diode and a first microstrip, and the first microstrip comprises a first metal wire, a second metal wire, and an intermediate medium;
the first metal wire and the second metal wire are disposed in parallel on a first surface of the intermediate medium along a first straight line, a first end of the first metal wire is opposite to a second end of the second metal wire, and a first spacing area with a spacing distance equal to a first value exists between the first end of the first metal wire and the second end of the second metal wire; and
a second end of the first metal wire is coupled to an anode of the diode.

2. The modulator according to claim 1, wherein the first microstrip further comprises a metal resonant ring, and the metal resonant ring is disposed on the first surface, and is located on a side of the first spacing area opposite the first metal wire and the second metal wire.

3. The modulator according to claim 2, wherein the metal resonant ring comprises a first ring segment with a length of a third value, and the first ring segment and the first straight line maintain a vertical shortest distance of a second value.

4. The modulator according to claim 2, wherein a connection line between a midpoint of the metal resonant ring and a midpoint of the first spacing area is perpendicular to the first straight line.

5. The modulator according to claim 2, wherein an open slot is provided on a side of the metal resonant ring that is away from the first metal wire and the second metal wire, and a slot spacing of the open slot is a fourth value.

6. The modulator according to claim 1, wherein the modulator further comprises a first coupler, a second end of the first coupler is a through end relative to a first end of the first coupler, a third end of the first coupler is a coupling end relative to the first end of the first coupler, and each first coupler corresponds to two first modulation circuits; and
the second end and the third end of the first coupler are respectively coupled, via first coupling, a corresponding first modulation circuit, wherein the first coupling refers to coupling the corresponding first coupler via a first end of the second metal wire of the first modulation circuit.

7. The modulator according to claim 6, wherein the modulator further comprises a second coupler and a power combiner, a second end of the second coupler is a through end relative to a first end of the second coupler, a third end of the second coupler is a coupling end relative to the first end of the second coupler, a fourth end of the first coupler is an isolation end relative to the first end of the first coupler, and each second coupler corresponds to two first couplers and one power combiner;
the second end and the third end of the second coupler are separately coupled, via second coupling, a corresponding first coupler, wherein the second coupling refers to coupling the corresponding second coupler via the first end of the first coupler; and
a first input end and a second input end of the power combiner are respectively coupled, via third coupling, a corresponding first coupler, wherein the third coupling refers to coupling the corresponding power combiner via the fourth end of the first coupler.

8. The modulator according to claim 1, wherein the first microstrip further comprises a ground metal plate and a third metal wire;
the ground metal plate is coupled to a second surface of the intermediate medium, the first surface and the second surface are two opposite surfaces of the intermediate medium, and a through hole running through the first surface and the second surface is provided on the intermediate medium;
a second end of the third metal wire penetrates into the through hole from the first surface and is coupled to the ground metal plate; and
a cathode of the diode is coupled to a first end of the third metal wire.

9. The modulator according to claim 1, wherein the first microstrip further comprises a ground metal plate, a third metal wire, a first air bridge, and a second air bridge;
the ground metal plate is coupled to a second surface of the intermediate medium, the first surface and the second surface are two opposite surfaces of the intermediate medium, and a through hole running through the first surface and the second surface is provided on the intermediate medium;
a second end of the third metal wire is coupled to the ground metal plate after extending from the first surface into the through hole; and
a body of the diode is grown on the first surface, a cathode of the diode is coupled to a first end of the third metal wire through the first air bridge, and the anode of the diode is coupled to the second end of the first metal wire through the second air bridge.

10. The modulator according to claim 9, wherein the intermediate medium is gallium arsenide, and the diode is based on gallium arsenide.

11. The modulator according to claim 9, wherein the body of the diode comprises a buffer layer, an epitaxial layer, and a passivation layer that are sequentially stacked on the first surface from bottom to top, and the cathode of the diode and the anode of the diode are respectively grown on two sides of an upper end surface of the buffer layer.

12. The modulator according to claim 11, wherein the diode further comprises a third air bridge, a vacant slot exists on the body of the diode, the vacant slot is located in a middle section of the buffer layer, the epitaxial layer, and the passivation layer, a first end of the third air bridge is coupled to the anode of the diode, and a second end of the third air bridge is coupled to the passivation layer on a side of the cathode of the diode across the vacant slot.

13. A manufacturing method, used for manufacturing a modulator, wherein the modulator comprises a first modulation circuit, the first modulation circuit comprises a diode and a first microstrip, and the first microstrip comprises a first metal wire, a second metal wire, and an intermediate medium; and the method comprises:
forming a first bright area on the intermediate medium; and obtaining the first metal wire and the second metal wire through etching based on the first bright area, wherein the first metal wire and the second metal wire are disposed in parallel on a first surface of the intermediate medium along a first straight line, a first end of the first metal wire is opposite to a second end of the second metal wire, a first spacing area with a spacing distance equal to a first value exists between the first end of the first metal wire and the second end of the second metal wire, and a second end of the first metal wire is coupled to an anode of the diode.

14. The manufacturing method according to claim 13, wherein the first microstrip further comprises a metal resonant ring; and the method further comprises:
obtaining the metal resonant ring through etching based on the first bright area, wherein the metal resonant ring is disposed on a second surface, and is located on a side of the first spacing area opposite the first metal wire and the second metal wire.

15. The manufacturing method according to claim 14, wherein the metal resonant ring comprises a first ring segment with a length of a third value, and the first ring segment and the first straight line maintain a vertical shortest distance of the second value.

16. The manufacturing method according to claim 15, wherein a connection line between a midpoint of the metal resonant ring and a midpoint of the first spacing area is perpendicular to the first straight line.

17. The manufacturing method according to claim 14, wherein an open slot is provided on a side of the metal resonant ring that is away from the first metal wire and the second metal wire, and a slot spacing of the open slot is a fourth value.

18. A transmitting apparatus, comprising a circuit board and a modulator wherein the modulator is disposed on the circuit board;
wherein the modulator comprising a first modulation circuit, wherein the first modulation circuit comprises a diode and a first microstrip, and the first microstrip comprises a first metal wire, a second metal wire, and an intermediate medium;
the first metal wire and the second metal wire are disposed in parallel on a first surface of the intermediate medium along a first straight line, a first end of the first metal wire is opposite to a second end of the second metal wire, and a first spacing area with a spacing distance equal to a first value exists between the first end of the first metal wire and the second end of the second metal wire; and
a second end of the first metal wire is coupled to an anode of the diode.

19. The transmitting apparatus according to claim 18, wherein the transmitting apparatus further comprises a frequency generator and a circuit board of a processing circuit, an output end of the processing circuit is coupled to a first input end of the modulator, and an output end of the frequency generator is coupled to a second input end of the modulator;
the frequency generator is configured to output a radio electromagnetic wave signal to the modulator;
the processing circuit is configured to output a data signal comprising at least one bit to the modulator; and
the modulator is configured to perform phase modulation on the radio electromagnetic wave signal based on the data signal, to obtain a phase-modulated wireless communication signal, and a phase of the wireless communication signal indicates a value of the at least one bit of the data signal.

20. The transmitting apparatus according to claim 18, wherein the transmitting apparatus further comprises a frequency multiplier, and the output end of the frequency generator is coupled to the second input end of the modulator through the frequency multiplier.
